(19) United States
(12) Patent Application Publication
(10) Pub. No.: US 2008/0103712 A1
(43) Pub. Date: May 1, 2008

(54) Diagnosis Apparatus For Switchgear

(75) Inventors: Dong-Myung KIM, Daejeon (KR); Tae-Ho Kwon, Daejeon (KR); Sun-kyu Choi, Daejeon (KR); Young-Geun Kim, Cheongju-si (KR); Do-Hoon Lee, Cheongju-si (KR)

Correspondence Address: SUGHRUE MION, PLLC, 2100 PENNSYLVANIA AVENUE, N.W., SUITE 800, WASHINGTON, DC, 20037, US

(73) Assignees: Korea Electric Power Corporation, Seoul (KR); LS Industrial Systems Co., Ltd., Seoul (KR)

(21) Appl. No.: 11/930,403

(22) Filed: Oct. 31, 2007

(30) Foreign Application Priority Data
Oct. 31, 2006 (KR) 10-2006-0106246

(51) Int. Cl. G01R 23/16; G01R 13/02

(52) U.S. Cl. 702/67; 324/76.19

(57) ABSTRACT

A diagnosis apparatus for a switchgear comprises a sensing unit which detects a partial discharge signal of the switchgear, an amplifying unit which amplifies the partial discharge signal detected from the sensing unit, a frequency spectrum generation unit which converts the amplified partial discharge signal into a frequency spectrum; and an analysis-diagnosis unit which analyzes and diagnoses the frequency spectrum.

### CROSS-REFERENCE TO RELATED APPLICATION

This application claims priority from Korean Patent Application No. 10-2006-0106246, filed on Oct. 31, 2006, the entire disclosure of which is incorporated herein by reference.

### BACKGROUND OF THE INVENTION

1. Field of the Invention

This invention relates to a diagnosis apparatus for a switchgear, more particularly, to a diagnosis apparatus for a switchgear capable of diagnosing a cause of a defect of a switchgear that is operating without dissembling the switchgear and capable of diagnosing a switchgear installed on the ground regardless of outside noises.

2. Description of the Related Art

A switchgear, one of power distribution equipment, is directly connected to a load and is used as a device for switching on or off power. A switchgear failure leads to losing control of industrial facilities. Further, the switchgear failure widely brings about a power outage of customers, and it debases electrical quality. About 120,000 switchgears for power distribution have been installed as of June, 2006 in South Korea.

Although a prevention-diagnosis method of the switchgear includes visual inspection, temperature and gaseous moisture measurement of an elbow connecting member, sound signal diagnosis, etc., it is difficult to check whether the inside of the switchgear which may be dangerous is an insulated state. Accordingly, introduction of a reliable partial discharge diagnosis by detecting an abnormal state of the switchgear has been urgently needed.

However, unlikely European medium voltage switchgears or gas insulated switchgears (“GIS”), which are positioned within buildings, switchgears installed in a ground power distribution system are positioned on a road, a green belt, etc., and thus are exposed to external noises, for example, traffic noises, electromagnetic waves, and raindrops. As a result, it is difficult to detect a discharge signal. Accordingly, it is necessary to develop a diagnosis apparatus applicable to the GIS of a pad-mounted structure.

### BRIEF SUMMARY OF THE INVENTION

The present invention provides a diagnosis apparatus for a switchgear capable of diagnosing a cause of a defect of a switchgear that is operating without dissembling the switchgear, and capable of diagnosing a switchgear installed on the ground regardless of external noises.

In an exemplary embodiment, a diagnosis apparatus for a switchgear comprises a sensing unit which detects a partial discharge (“PD”) signal of the switchgear; an amplification unit which amplifies the PD signal detected from the sensing unit; a frequency spectrum generation unit which converts the amplified PD signal into a frequency spectrum, and an analysis-diagnosis unit which analyses and diagnoses the frequency spectrum.

The sensing unit may be an ultrahigh frequency (“UHF”) sensor.

The UHF sensor may use a frequency of a band of about 300 MHz to about 3 GHz.

The UHF sensor may be an internal UHF sensor installed in the inside of the switchgear.

The internal UHF sensor may include a first sensor housing having a first sensor to detect the PD signal of the inside of the switchgear, an insulation member which is interposed between the first sensor housing and an outer box of the switchgear and insulates the first sensor housing from the switch gear, a cover which covers the first sensor housing, and a sealing member interposed between the first sensor housing and cover to maintain an air-tightness of the inside of the first sensor housing.

The first sensor housing may further include an Archimedean spiral antenna.

The first sensor may have a minimum operating frequency at which a whole length of the antenna is the same as a wavelength of the partial discharge signal, and impedance characteristics of the first sensor have no relation to a radiation pattern at a frequency band higher than the minimum operating frequency.

The UHF sensor may be an external UHF sensor installed in the outside of the switchgear.

The external UHF sensor may include a second sensor housing having a second sensor to detect the PD signal of the switchgear, and a mounting portion which mounts the second sensor housing on the switchgear.

The external UHF sensor may further include a log periodic antenna.

The external UHF sensor may further include a shielding member to shield outside noises.

The analysis-diagnosis unit may include a controller which controls the amplification unit and the frequency spectrum generation unit, a display which displays the frequency spectrum and an analyzer, which analyzes the frequency spectrum to generate a partial discharge pattern.

The analyzer may use a phase resolved partial discharge analysis (“PRPDA”) algorithm.

The analyzer further may include a statistical analyzer.

The statistical analyzer may use back-propagation algorithm and an L2 distance classifier algorithm.

### BRIEF DESCRIPTION OF THE DRAWINGS

The above and other features and advantages of the present invention will be more apparent from the following detailed description in conjunction with the accompanying drawings, in which,

FIG. 1 is a block diagram showing a diagnosis apparatus for a switchgear in accordance with an exemplary embodiment of the present invention;

FIG. 2 is a cross sectional view showing an internal UHF sensor in accordance with an exemplary embodiment of the present invention;

FIG. 3 is a view showing an antenna of the internal UHF sensor in accordance with an exemplary embodiment of the present invention;

FIG. 4 is a perspective view showing an external UHF sensor in accordance with an exemplary embodiment of the present invention; and

FIG. 5 is a perspective view showing an antenna of the external UHF sensor in accordance with an exemplary embodiment of the present invention.

### DETAILED DESCRIPTION OF THE EMBODIMENTS

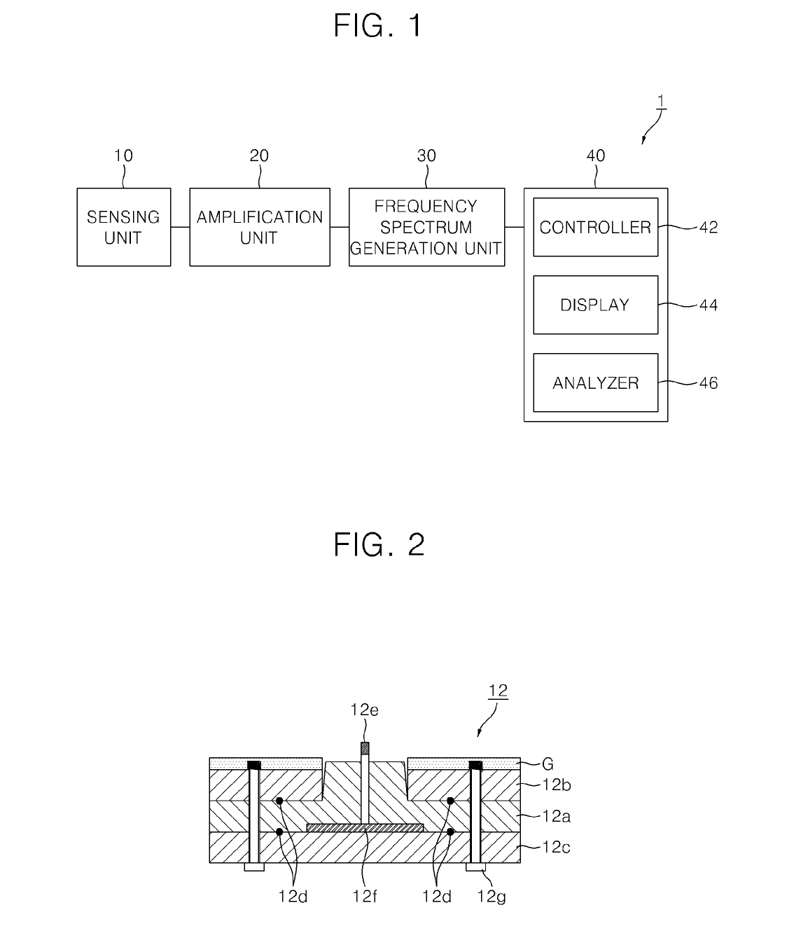

FIG. 1 is block diagram showing a diagnosis apparatus for a switchgear in accordance with an exemplary embodiment of the present invention.

Referring to FIG. 1, a diagnosis apparatus 1 for a switchgear includes a sensing unit 10, an amplification unit 20, a frequency spectrum generation unit 30, and an analysis-diagnosis unit 40.

The sensing unit 10 detects a partial discharge (“PD”) signal of the switchgear. The PD signal is generated by the degradation of hardness and softness of the switchgear or by an internal insulation problem.

In an exemplary embodiment of the present invention, the sensing unit 10 is comprised of an ultrahigh frequency (“UHF”) sensor that is relatively free from an electromagnetic wave noise. The UHF sensor measures the PD signal at a frequency band of about 300 MHz to about 3 GHz which is less influenced by electromagnetic waves.

The sensing unit 10 may be an internal UHF sensor 12 as shown in FIG. 2 or an external UHF sensor 14 as shown in FIG. 4. The internal UHF sensor 12 is mainly installed at the interior of a newly produced switchgear, and the external UHF sensor 14 is mainly installed at the exterior of an existing switchgear.

As shown in FIG. 2, the internal UHF sensor 12 includes a first sensor housing 12a, an insulation member 12b, a cover 12c, and sealing members 12d.

The first sensor housing 12a is formed in a cylindrical shape and includes a first sensor 12e and an antenna 12f installed therein.

The first sensor 12e detects a PD signal from the inside of a switchgear G. The first sensor housing 12a is formed of a material that can endure circumstances of the inside of the switchgear G to protect the first sensor 12e.

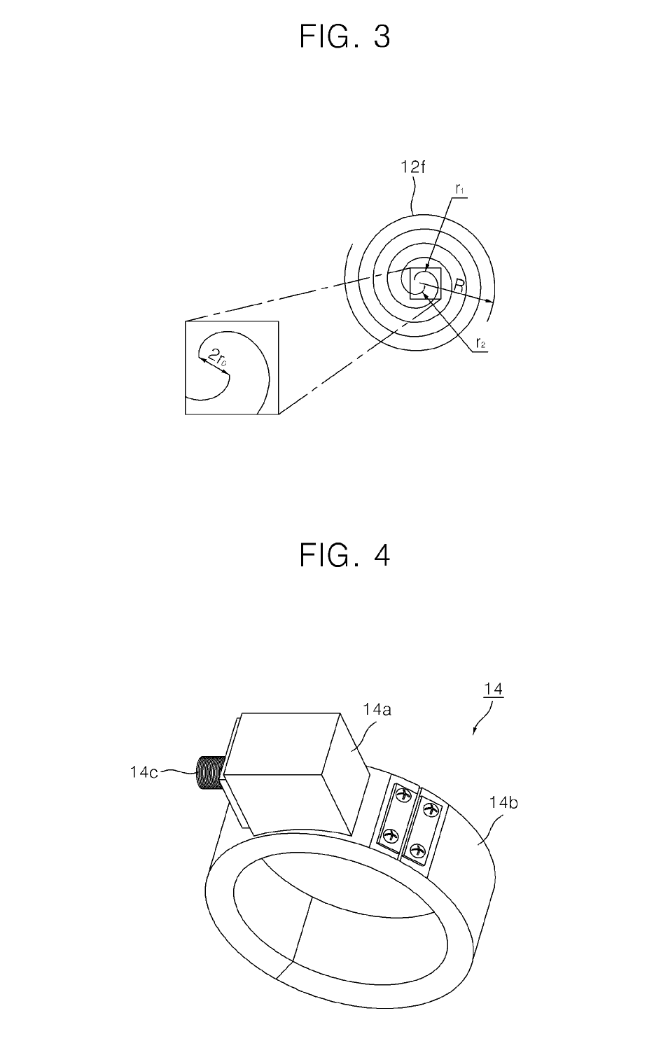

The antenna 12f of the first sensor housing 12a may be an Archimedean spiral antenna, as shown in FIG. 3. Referring to FIG. 3, the Archimedean spiral antenna has the following features.

r₁=r₀Ø, r₂=r₀(Ø−π)

r₀: spiral constant

Ø: rotation angle

R: diameter of a sensor

Preferably, the first sensor 12e has a minimum operating frequency at which the whole length of the antenna 12f is the same as the wavelength of the PD signal. And at a frequency band higher than the minimum operating frequency, impedance characteristics of the first sensor 12e have no relation to a radiation pattern.

Referring back to FIG. 2, the insulation member 12b is interposed between the first sensor housing 12a and an outer box of the switchgear G to insulate the first sensor housing 12a from the switchgear G. Since the internal UHF sensor 12 is installed at the interior of the switchgear G, it should be insulated from the outer box of the switchgear G. The insulation member 12b functions as insulating the first sensor 12e from the outer box of the switchgear G. In an exemplary of the present invention, the insulation member 12b is comprised of a coupling. The coupling includes a penetration hole through which the first sensor 12e is inserted.

The cover 12c covers the upper surface of the first senor housing 12a. The cover 12c is formed of a material that can endure circumstances of the inside of the switchgear G to protect the antenna 12f

The sealing members 12d are interposed between the first sensor housing 12a and the cover 12c to seal off the first sensor housing 12a. The sealing member 12d may be interposed between the first sensor housing 12a and the insulation member 12b. In an exemplary, the sealing member 12d is formed of an O-ring member.

As shown in FIG. 4, the external UHF sensor 14 includes a second sensor housing 14a and a mounting portion 14c.

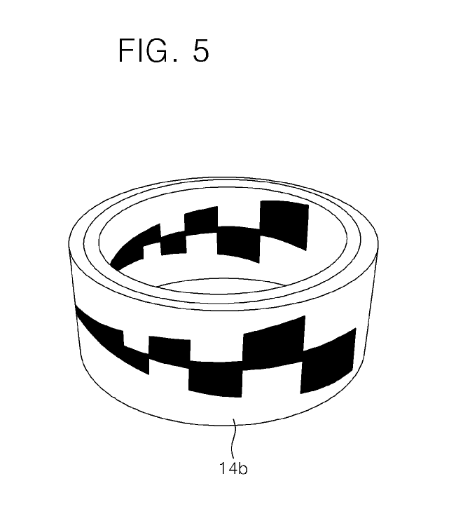

The second sensor housing 14a includes a second sensor (not shown) to detect a PD signal from the switchgear. The second sensor detects the PD signal of the inside of the switchgear at the outside of the switchgear. For doing this, the external UHF sensor 14 may have a log periodic antenna 14b as shown in FIG. 5.

The external UHF sensor 14 may include a shielding member (not shown) to shield outside noises. Since the external UHF sensor 14 is exposed to many outside noises, compared with the internal UHF sensor 12, the external UHF sensor 14 further includes the shielding member to minimize the influence of the outside noises.

The mounting portion 14c connects the second sensor housing 14a to the switchgear. As shown in FIGS. 4 and 5, the mounting portion 14c is formed in a jack shape so that the mounting portion 14c can be easily mounted or dismounted to or from a bushing of the switchgear. As a result, the external UHF sensor 14 is easily mounted to the switchgear only by inserting the mounting portion 14c of the jack shape into a groove formed in the bushing.

Referring back to FIG. 1, the amplification unit 20 amplifies the PD signal detected from the sensing unit 10. The amplification unit 20 is comprised of a pre-amplifier to amplify a signal-to-noise ratio of the PD signal and a peripheral electromagnetic wave noise. Then it is easy to separate the pure PD signal from the noise.

The frequency spectrum generation unit 30 converts the PD signal amplified from the amplification unit 20 into a frequency spectrum. The frequency spectrum generation unit 30 is comprised of a spectrum analyzer.

The analysis-diagnosis unit 40 analyzes and diagnoses the frequency spectrum by software.

The analysis-diagnosis unit 40 includes a controller 42, a display 44, and an analyzer 46.

The controller 42 controls the amplification unit 20 and the frequency spectrum generation unit 30 by using an external device, for example, a laptop computer. The controller 42 mainly sets a frequency, zero-span, a sweep time, and transfer data format.

The display 44 displays the frequency spectrum. In other words, the display 44 displays data received from the frequency spectrum generation unit 30 on a screen of the laptop computer for example. More specifically, the display 44 automatically plots a measurement range, a measurement unit, and a measurement condition for data received from the frequency spectrum generation unit 30. The analyzer 46, an important element of the analysis-diagnosis unit 40, analyzes the frequency spectrum to generate a partial discharge pattern. The analyzer 46 analyzes the measured data so as to display a three-dimensional image, generates a partial discharge pattern, and extracts about twenty parameters to judge defects of power facilities.

For doing this, the analyzer 46 uses a phase resolved partial discharge analysis (“PRPDA”) algorithm. The analyzer 46 analyzes the measured data to be displayed in three-dimension by using the PRPDA algorithm.

The analyzer 46 further includes a statistical analyzer (not shown) to extract about twenty parameters. The statistical analyzer judges defects of the switchgear by using a back-propagation algorithm and an L2 distance classifier algorithm.

As described above, the diagnosis apparatus according to an exemplary embodiment of the present invention can exactly diagnose the switchgear by using the UHF sensor which is less influenced by a noise.

Furthermore, the diagnosis apparatus according to an exemplary embodiment of the present invention can diagnose the insulation state of the switchgear without dissembling the switchgear irrespective of newly-produced switchgears or existing switchgears, by using the internal UHF sensor or the external UHF sensor.

In addition, the diagnosis apparatus according to an exemplary embodiment of the present invention extracts about twenty parameters by using the statistical analyzer. Since the statistical analyzer utilizes a back-propagation algorithm and an L2 distance classifier algorithm to judge a defect of the switchgear, it is possible to diagnose the switchgear with high reliability.

Although the present invention has been described with reference to certain exemplary embodiments thereof, it will be understood by those of skill in this art that a variety of modifications and variations may be made to the present invention without departing from the spirit and scope of the present invention as defined in the appended claims and their functional equivalents.

What is claimed is:

1. A diagnosis apparatus for a switchgear, comprising:
a sensing unit which detects a partial discharge signal of the switchgear;
an amplification unit which amplifies the partial discharge signal detected from the sensing unit;
a frequency spectrum generation unit which converts the amplified partial discharge signal into a frequency spectrum; and
an analysis-diagnosis unit which analyzes and diagnoses the frequency spectrum.

2. The diagnosis apparatus for the switchgear of claim 1, wherein the sensing unit is an ultrahigh frequency (“UHF”) sensor.

3. The diagnosis apparatus for the switchgear of claim 2, wherein the UHF sensor uses a frequency band of about 300 MHz to about 3 GHz.

4. The diagnosis apparatus for the switchgear of claim 2, wherein the UHF sensor is an internal UHF sensor installed at the inside of the switchgear.

5. The diagnosis apparatus for the switchgear of claim 4, wherein the internal UHF sensor comprises:
a first sensor housing having a first sensor to detect the partial discharge signal of the inside of the switchgear;
an insulation member which is interposed between the first sensor housing and an outer box of the switchgear and insulates the first sensor housing from the switchgear;
a cover which covers the first sensor housing; and
a sealing member interposed between the first sensor housing and the cover to maintain an air-tightness of the inside of the first sensor housing.

6. The diagnosis apparatus for the switchgear of claim 5, wherein the first sensor housing further includes an Archimedean spiral antenna.

7. The diagnosis apparatus for the switchgear of claim 6, wherein the first sensor has a minimum operating frequency at which a whole length of the antenna is the same as a wavelength of the partial discharge signal, and impedance characteristics of the first sensor have no relation to a radiation pattern at a frequency band higher than the minimum operating frequency.

8. The diagnosis apparatus for the switchgear of claim 2, wherein the UHF sensor is an external UHF sensor installed at the outside of the switchgear.

9. The diagnosis apparatus for the switchgear of claim 2, wherein the external UHF sensor comprises:
a second sensor housing having a second sensor to detect the partial discharge signal of the switchgear; and
a mounting portion which mounts the second sensor housing on the switchgear.

10. The diagnosis apparatus for the switchgear of claim 9, wherein the external UHF sensor further includes a log periodic antenna.

11. The diagnosis apparatus for the switchgear of claim 10, wherein the external UHF sensor further includes a shielding member to shield external noises.

12. The diagnosis apparatus for the switchgear of claim 2, wherein the analysis-diagnosis unit comprises:
a controller which controls the amplification unit and the frequency spectrum generation unit;
a display which displays the frequency spectrum; and
an analyzer which analyzes the frequency spectrum to generate a partial discharge pattern.

13. The diagnosis apparatus for the switchgear of claim 12, the analyzer uses a phase resolved partial discharge analysis (“PRPDA”) algorithm.

14. The diagnosis apparatus for the switchgear of claim 13, wherein the analyzer further includes a statistical analyzer.

15. The diagnosis apparatus for the switchgear of claim 14, the statistical analyzer uses a back-propagation algorithm and an L2 distance classifier algorithm.
